(19) United States
(12) Patent Application Publication
(10) Pub. No.: US 2024/0122016 A1
(43) Pub. Date: Apr. 11, 2024

(54) DISPLAY PANEL, DISPLAY DEVICE AND METHOD OF MANUFACTURING DISPLAY PANEL

(71) Applicant: Yungu (Gu’an) Technology Co., Ltd., Langfang (CN)

(72) Inventors: Zhimin YAN, Langfang (CN); Siming GAO, Langfang (CN); Shupeng WANG, Langfang (CN); Shaoyang QIN, Langfang (CN)

(73) Assignee: Yungu (Gu’an) Technology Co., Ltd., Langfang (CN)

(21) Appl. No.: 18/545,065

(22) Filed: Dec. 19, 2023

Related U.S. Application Data
(63) Continuation of application No. PCT/CN2023/096107, filed on May 24, 2023.

(30) Foreign Application Priority Data
Jun. 10, 2022 (CN) 202210654650.2
Nov. 30, 2022 (CN) 202211522011.7

(51) Int. Cl. H10K 59/131; H10K 59/12

(52) U.S. Cl. CPC H10K 59/131; H10K 59/1201

(57) ABSTRACT

A display panel, a display device and a method of manufacturing the display panel. The display panel includes a display region, and the display region includes a first region and a second region. The display panel includes a base body and a first electrode layer. At least a portion of the first electrode layer is located on a side of the base body, the first electrode layer includes a plurality of first electrodes and a plurality of openings, the first electrodes are located within the first region, and the openings are located within the second region. The display panel is provided with a blocking structure which is configured to block the first electrodes from extending to the second region.

### CROSS REFERENCE TO RELATED APPLICATION

The present application is a continuation of International Application No. PCT/CN2023/096107, filed on May 24, 2023, which claims priority to Chinese Patent Application No. 202210654650.2, filed on Jun. 10, 2022, titled with “DISPLAY PANEL, METHOD OF MANUFACTURING AND DISPLAY DEVICE”, and priority to Chinese Patent Application No. 202211522011.7, filed on Nov. 30, 2022, titled “DISPLAY PANEL, DISPLAY DEVICE AND METHOD OF MANUFACTURING DISPLAY PANEL”, all of which are hereby incorporated by reference in their entireties.

### TECHNICAL FIELD

The present application relates to the technical field of display, and in particular to a display panel, a display device and a method of manufacturing the display panel.

### BACKGROUND

The patterning of an electrode layer is an important means to improve the transmittance of a screen body of a display panel, which can be achieved by laser ashing. For example, after evaporating the electrode layer, infrared laser can be used to enter into a back side of a substrate to achieve the laser etching of the electrode layer, thereby achieving the patterning of the electrode layer. However, after the laser ashing, electrodes included in the patterned electrode layer will occur edge warping, thereby reducing the reliability of packaging.

### SUMMARY

Embodiments of the present application provide a display panel, a display device and a method of manufacturing the display panel, which can improve the reliability of the encapsulation.

In a first aspect, embodiments in the present application provides a display panel. The display panel includes a display region, and the display region includes a first region and a second region. The display panel includes a base body and a first electrode layer. At least a portion of the first electrode layer is located on a side of the base body, the first electrode layer includes a plurality of first electrodes and a plurality of openings, the first electrodes are located within the first region, and the openings are located within the second region. The display panel is provided with a blocking structure which is configured to block the first electrodes from extending to the second region.

In a second aspect, embodiments in the present application provides a display panel that includes a display region including a first region and a second region. The display panel includes
a base body; and
a first electrode layer, at least a portion of the first electrode layer located on a side of the base body, the first electrode layer including a plurality of first electrodes and a plurality of openings, the first electrodes located within the first region, and the openings located within the second region.

A surface of the base body facing the first electrode layer includes
a first surface, located within the first region; and
a second surface, located within the second region.

In a thickness direction of the display panel, the first surface and the second surface form a first height difference at a junction place of the first region and the second region to form a blocking structure.

In a third aspect, embodiments in the present application provides a display panel that includes a display region including a first region and a second region. The display panel includes
a base body; and
a first electrode layer, at least a portion of the first electrode layer being located on a side of the base body, and the first electrode layer including a plurality of first electrodes and a plurality of openings.

The first region is a first electrode material reserving region, and the second region is a first electrode material removing region; the first electrodes are located within the first electrode material reserving region, and the openings are located within the first electrode material removing region; a portion of the first electrode material layer located within the first electrode material reserving region is reserved to form the first electrodes, and a portion of the first electrode material layer located within the first electrode material removing region is removed to form the openings.

The display panel is provided with a blocking structure which is configured to disconnect a reserved portion of the first electrode material layer from a removed portion of the first electrode material layer before the openings are formed.

In a fourth aspect, embodiments in the present application provides a method of manufacturing a display panel, the display panel includes a display region, and the display region includes a first region and a second region. The method includes
providing a base body provided with a blocking structure;
providing a first electrode material layer located on a side of the base body, so that the first electrode material layer is broken at the boundary between the first region and the second region by the blocking structure; and
removing by laser a portion of the first electrode material layer located within the second region to form a plurality of openings, forming a plurality of first electrodes by a reserved portion of the first electrode material layer, and forming the first electrode layer by the first electrodes and the openings.

In a fifth aspect, embodiments in the present application provides a display device, including the display panel according to any one of embodiments in the first aspect to the third aspect as described above.

In the display panel provided in the embodiments of the present application, the display region of the display panel includes the first region and the second region, and the display panel includes the base body and the first electrode layer. At least portion of the first electrode layer is located on a side of the base body, the first electrode layer includes the first electrodes and the openings, the first electrodes are located within the first region, the openings are located within the second region, and the display panel is provided with the blocking structure for blocking the first electrodes from extending to the second region. The first electrode layer is close to a subsequent encapsulation layer, and the shape of the first electrode layer will affect the encapsulation effect. In the process of manufacturing the display panel, the first electrode material layer located within the first region and the second region will be formed firstly. Before removing a portion of the first electrode material layer by laser ashing, the blocking structure can block the first electrodes from extending to the second region, that is, the blocking structure is configured to disconnect the reserved portion of the first electrode material layer from the removed portion of the first electrode material layer before removing a portion of the first electrode material layer by the laser ashing. In other words, the blocking structure is configured to enable the first electrode material layer used to form the first electrode layer to be broken at the junction place of the first region and the second region, so that the portion of the first electrode material layer located within the first region and the portion of the first electrode material layer located within the second region are separated from each other. During removing the portion of the first electrode material layer located within the second region by the laser ashing, the problem that an edge of a portion of the first electrode material layer located within the first region curls up due to the adhesion between a portion of the first electrode material layer located within the second region and a portion of the first electrode material layer located within the first region can be solved. That is, the problem that an edge of the first electrode facing the second region curling up can be improved, so as to avoid the curling up edge of the first electrode from scratching the encapsulation layer, thereby improving the reliability of the encapsulation.

### BRIEF DESCRIPTION OF THE DRAWINGS

In order to more clearly illustrate the technical solution of the embodiments of the present application, the drawings required to be used in the embodiments of the present application will be briefly introduced below. For those skilled in the art, other drawings can also be obtained according to these drawings without the inventive labor.

FIG. 1 shows a top structural schematic view of a display panel according to an embodiment of the present application;

FIG. 2 to FIG. 14 show sectional views in B-B direction of FIG. 1 in different embodiments; and

FIG. 15 shows a flow chart of a method of manufacturing a display panel according to an embodiment of the present application.

### DETAILED DESCRIPTION

Features and exemplary embodiments in various aspects of the present application will be described in detail below. In order to make the objects, technical solutions and advantages of the present application clearer, the present application will be further described in detail below in conjunction with the drawings and the specific embodiments. It should be understood that the specific embodiments described here are only configured to explain the present application, not to limit the present application. It is apparent to one skilled in the art that the present application can be practiced without some of these specific details. The description of the embodiments below is only to provide a better understanding of the present application by showing examples of the present application.

The patterning of a cathode layer is an important means to improve the transmittance of a screen body of a display, which can be realized by laser ashing. For example, after evaporating the cathode layer, infrared laser can be used to enter into a side of a substrate away from the cathode layer to achieve laser etching of the cathode layer, so as to achieve the patterning of the cathode layer. However, after the laser ashing, an edge of a portion of the cathode layer which is reserved may curl up, which may lead to a negative impact on the subsequent encapsulation and reduce the reliability of the encapsulation.

In order to solve the above-mentioned technical problems, the present application is filed. In order to better understand the present application, a display panel and a display device provided by the present application are described below in conjunction with the drawings.

Referring to FIG. 1, FIG. 1 shows a top structural schematic view of a display panel 10 according to an embodiment of the present application. As shown in FIG. 1, the display panel 10 may include a display region AA and a non-display region NA. The display region AA may include a first region 11 and a second region 12. The first region 11 of the display panel 10 may be used to set pixel units. The first regions 11 may be arranged in an array. The second region 12 may be a region between two adjacent first regions 11. Optionally, the second region 12 may be arranged around the first region 11. In some other embodiments, the display panel may include only the display region AA, and not include the non-display region NA.

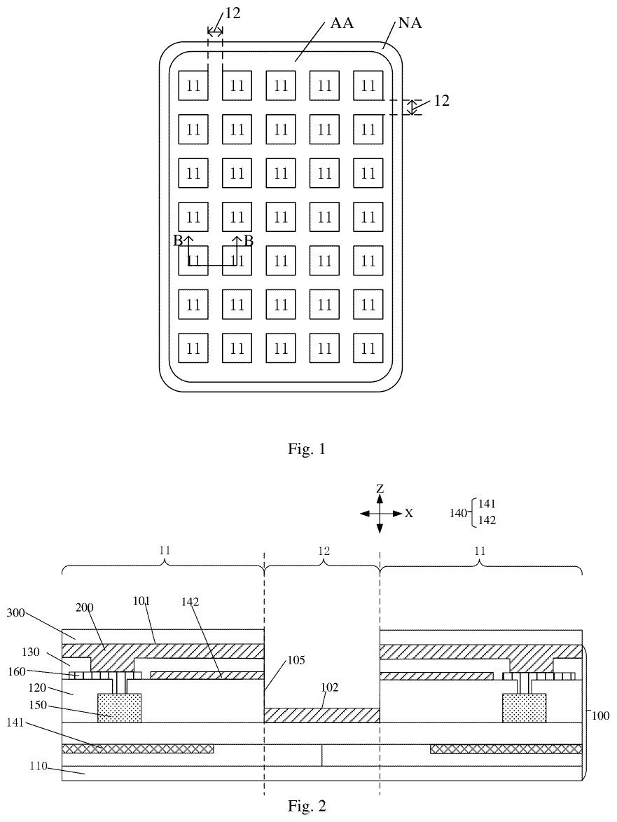

Referring to FIG. 1 and FIG. 2, FIG. 2 shows a sectional view in B-B direction of FIG. 1.

As shown in FIG. 1 and FIG. 2, the embodiments in a first aspect of the present application provide the display panel 10. The above-mentioned display panel 10 includes the display region AA, and the display region AA includes the first region 11 and the second region 12. The display panel 10 includes a base body 100 and a first electrode layer 300. At least a portion of the first electrode layer 300 is located on a side of the base body 100, the first electrode layer 300 includes a plurality of first electrodes 310 and a plurality of openings 320, the first electrodes 310 are located within the first region 11, and the openings 320 are located within the second region 12. The first region 11 is a first electrode material reserving region, and the second region 12 is a first electrode material removing region; in other words, the first electrodes 310 are located within the first electrode material reserving region, the openings 320 are located within the first electrode material removing region, and part of the first electrode material layer located in the first electrode material reserving region is reserved to form the first electrodes 310; a portion of the first electrode material layer located within the first electrode material reserving region is reserved to form the first electrodes 310, and a portion of the first electrode material layer located within the first electrode material removing region is removed to form the openings 320. The display panel 10 is provided with a blocking structure, and the blocking structure is used to block the first electrodes 310 from extending to the second region 12. In other words, the display panel 10 is provided with the blocking structure, and the blocking structure is configured to disconnect a reserved portion of the first electrode material layer from a removed portion of the first electrode material layer before the opening 32 is formed.

In the display panel 10 provided by the embodiments of the present application, the display region AA of the display panel 10 includes the first region 11 and the second region 12, and the display panel 10 includes the base body 100 and the first electrode layer 300. The first electrode layer 300 includes the first electrodes 310 and the openings 320, and the base body 100 is provided with the blocking structure, and the blocking structure is enable to block the first electrodes 310 from extending to the second region 12. In other words, the display panel 10 is provided with the blocking structure, and the blocking structure is configured to disconnect the reserved portion of the first electrode material layer from the removed portion of the first electrode material layer before the opening 32 is formed. The first electrode layer 300 is close to a subsequent encapsulation layer, and the shape of the first electrode layer 300 will affect the encapsulation effect. In the process of manufacturing the display panel 10, the first electrode material layer located within the first region 11 and the second region 12 and used to form the first electrode layer 300 will be formed firstly. Before removing a portion of the first electrode material layer by laser ashing, the blocking structure can block the first electrodes 310 from extending to the second region 12, that is, the blocking structure is configured to enable the first electrode material layer used to form the first electrode layer 300 to be broken at a junction place of the first region 11 and the second region 12, so that the portion of the first electrode material layer located within the first region 11 and the portion of the first electrode material layer located within the second region 12 are separated from each other. During removing the portion of the first electrode material layer located within the second region 12 by the laser ashing, the problem that an edge of a portion of the first electrode material layer located within the first region 11 curls up due to the adhesion between a portion of the first electrode material layer located within the second region 12 and a portion of the first electrode material layer located within the first region 11 can be solved. That is, the problem that an edge of the first electrode 310 facing the second region 12 curls up can be improved, so as to avoid the curling up edge of the first electrode 310 from scratching the encapsulation layer, thereby improving the reliability of the encapsulation.

The base body 100 may be arranged in various ways, and the base body 100 may further include a pixel driving circuit. For example, the base body 100 may include a substrate 110 and a number of layer structures stacked with one another on a side of the substrate 110. For example, the base body 100 includes the substrate 110, a planarized layer 120, a pixel defining layer 130 and a light-emitting layer 200. The planarized layer 120 is located on a side of the substrate 110, the pixel defining layer 130 is located on a side of the planarized layer 120 away from the substrate 110, and at least a portion of the light-emitting layer 200 is located on a side of the pixel defining layer 130 away from the planarized layer 120. At least a portion of the first electrode layer 300 is located on a side of the light-emitting layer 200 away from the pixel defining layer 130.

The base body 100 further includes a signal line layer 150 and a second electrode layer 160. The signal line layer 150 is located on a side of the planarized layer 120 facing the substrate 110, the second electrode layer 160 is located on a side of the planarized layer 120 facing the substrate 110, the second electrode layer 160 is located between the planarized layer 120 and the pixel defining layer 130, the signal line layer 150 and the second electrode layer 160 are located on two sides of the planarized layer 120 and connected with each other by passing through the planarized layer 120, and the first electrode layer 300 and the second electrode layer 160 are located on two sides of the light-emitting layer 200. Optionally, the second electrode layer 160 includes a plurality of pixel electrodes distributed in an array. The pixel defining layer 130 includes an isolating part and pixel openings enclosed and formed by the isolating part, and the pixel electrodes are arranged to correspond to the pixel openings respectively. Light-emitting structures are provided in the pixel openings respectively, and the pixel electrodes of the second electrode layer 160 and the first electrodes 310 of the first electrode layer 300 interact to drive the light-emitting structures to emit light.

Optionally, the light-emitting layer 200 includes a carrier layer, and the carrier layer includes a hole injection layer, a hole transport layer, an electron transport layer, an electron injection layer and the like. The light-emitting structure is located between the hole transport layer and the electron transport layer. In some embodiments, the carrier layer may further include an electronic blocking layer and a hole blocking layer.

In some other optional embodiments, referring further to FIG. 1 and FIG. 2, a surface of the base body 100 facing the first electrode layer 300 includes a first surface 101 and a second surface 102. The first surface 101 is located within the first region 11, and the second surface 102 is located within the second region 12. In a thickness direction Z of the display panel 10, the first surface 101 and the second surface 102 form a first height difference at the junction place of the first region 11 and the second region 12 to form the blocking structure. In one of the embodiments, the first height difference is larger than a thickness of the first electrode 310 in the thickness direction Z of the display panel 10.

In these optional embodiments, the surface of the base body 100 includes the first surface 101 located within the first region 11 and the second surface 102 located within the second region 12. Since the first surface 101 and the second surface 102 form the first height difference at the junction place of the first region 11 and the second region 12, during forming the first electrode material layer for preparing the first electrode layer 300, the first electrode material layer is broken at the junction place of the first region 11 and the second region 12, so that the blocking structure formed by the first height difference can solve the problem that the edge of the first electrode 310 facing the second region 12 curls up, so as to improve the reliability of the encapsulation.

In addition, in the embodiments of the present application, there is the first height difference between the first surface 101 and the second surface 102 at the junction place of the first region 11 and the second region 12 to form the blocking structure, that is, the blocking structure is formed by a structure of the base body 100 itself, which can reduce the manufacturing cost of the display panel 10.

In some other embodiments, as shown in FIG. 2, the first surface 101 is closer to the first electrode layer 300 than the second surface 102 to the first electrode layer 300 in the thickness direction Z of the display panel 10. Optionally, the first electrodes 310 are attached to the first surface 101 of the base body 100. That is, the second surface 102 located within the second region 12 is arranged to be closer to the substrate 110 than the first surface 101 located within the first region 11 to the substrate 110, and the structures such as the pixel defining layer 130 and the planarized layer 120 may be processed by patterning to form the blocking structure. For example, the structures, such as the pixel defining layer 130 and the planarized layer 120 located within the second region 12, can be removed to form a second avoidance slot 103 located within the second region 12.

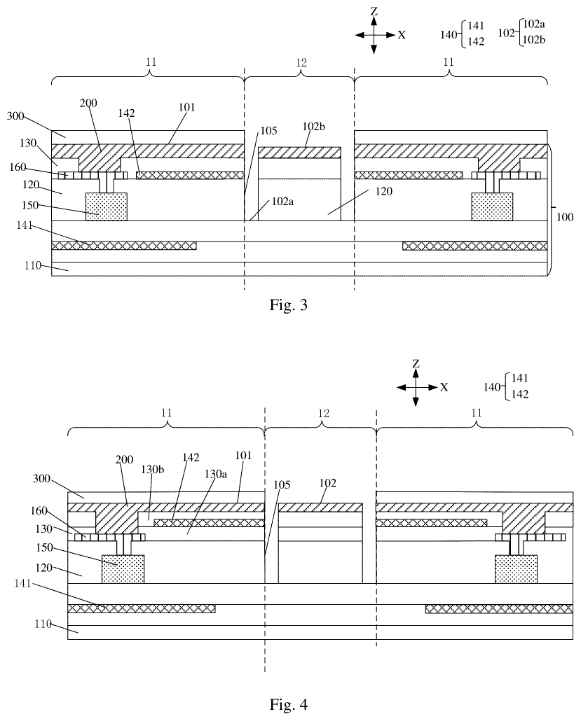

In some optional embodiments, as shown in FIG. 3, the second surface 102 includes a first sub-face 102a and a second sub-face 102b, and the first sub-face 102a is located between the first surface 101 and the second sub-face 102b in a horizontal direction perpendicular to the thickness direction Z of the display panel 10. The first sub-face 102a and the second sub-face 102b form a second height difference in the thickness direction Z of the display panel 10. The horizontal direction is parallel to a display face of the display panel 10. For example, the horizontal direction is the X direction in FIG. 3. Optionally, the first height difference described above is formed between the first sub-face 102a and the first surface 101. Optionally, the first height difference is equal to the second height difference.

In these optional embodiments, in the horizontal direction X perpendicular to the thickness direction Z of the display panel 10, the first sub-face 102a is located between the first surface 101 and the second sub-face 102b, and the first sub-face 102a and the first surface 101 form the first height difference in the thickness direction Z of the display panel 10 to form the blocking structure.

In some other embodiments, as shown in FIG. 3, in the thickness direction Z of the display panel 10, the second sub-face 102b and the first surface 101 are closer to the first electrode layer 300 than the first sub-face 102a to the first electrode layer 300. That is, the first sub-face 102a is closer to the substrate 110 than the second sub-face 102b and the first surface 101 to the substrate 110. The structures such as the pixel defining layer 130 and the planarized layer 120 may be processed by patterning to form the blocking structure. For example, the structures, such as a portion of the pixel defining layer 130 and a portion of the planarized layer 120 located within the second region 12, can be removed to form a gully between the first surface 101 and the second sub-face 102b, and a bottom wall face of the gully is the first sub-face 102a.

Optionally, as shown in FIG. 3, the second sub-face 102b and the first surface 101 are flush with each other in the horizontal direction X. Therefore, the second sub-face 102b and the first surface 101 can be prepared and formed in the same process step, which can simplify the preparation process of the display panel 10.

As mentioned above, in some embodiments, the base body 100 includes the substrate 110, the planarized layer 120, the pixel defining layer 130 and the light-emitting layer 200. The planarized layer 120 is located on a side of the substrate 110. The pixel defining layer 130 is located on the side of the planarized layer 120 away from the substrate 110. At least a portion of the light-emitting layer 200 is located on the side of the pixel defining layer 130 away from the planarized layer 120. At least a portion of the first electrode layer 300 is arranged on the side of the light-emitting layer 200 away from the pixel defining layer 130.

In some embodiments, as shown in FIG. 1 to FIG. 3, the base body 100 includes at least one sheltering layer 140, the at least one sheltering layer 140 is located within the first region 11, and an orthographic projection of the at least one sheltering layer 140 on the substrate 110 covers an orthographic projection of the first electrode 310 on the substrate 110.

In these optional embodiments, the at least one sheltering layer 140 can block the first electrode material layer located within the first region 11, the at least one sheltering layer 140 can be used as a mask plate for laser ashing the first electrode material layer, and the at least one sheltering layer 140 can shelter from the laser to avoid the laser affecting the first electrode material layer located within the first region 11.

The at least one sheltering layer 140 may be provided in various ways. The at least one sheltering layer 140 may include only one sheltering layer, or the at least one sheltering layer 140 may include two sheltering layers, or the at least one sheltering layer 140 may include three sheltering layers, or the at least one sheltering layer 140 may include more than three sheltering layers, which is not limited herein.

In some optional embodiments, as shown in FIG. 2 and FIG. 3, the at least one sheltering layer 140 includes a first sheltering layer 141 and a second sheltering layer 142. The second sheltering layer 142 is closer to the first electrode layer 300 than the first sheltering layer 141 to the first electrode layer 300 in the thickness direction Z of the display panel 10, and the second sheltering layer 142 is closer to the second region 12 than the first sheltering layer 141 to the second region 12 in the horizontal direction X perpendicular to the thickness direction Z of the display panel 10.

In these optional embodiments, in the horizontal direction X, the second sheltering layer 142 is closer to the second region 12, that is, the second sheltering layer 142 is closer to the edge of the first electrode 310 facing the second region 12. A distance between the second sheltering layer 142 and the first electrode layer 300 is smaller in the thickness direction Z. During the laser ashing, the amount of laser entering into the first region 11 due to the diffraction of the laser at the edge of the second sheltering layer 142 can be reduced, thereby better solving the problem that the edge of the first electrode 310 facing the second region 12 curls up during the laser ashing.

Optionally, the second sheltering layer 142 is located on the side of the planarized layer 120 facing or away from the substrate 110, or the second sheltering layer 142 is located within the pixel defining layer 130.

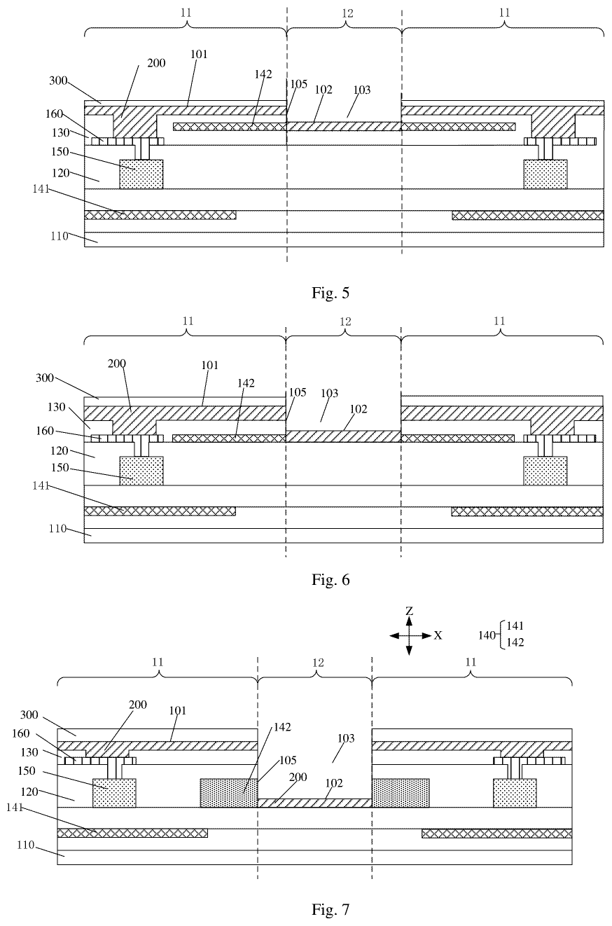

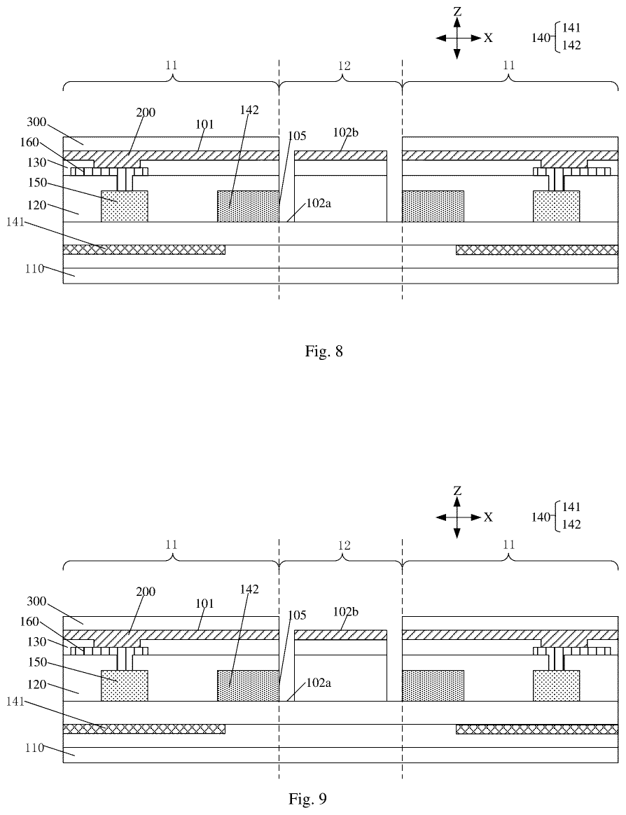

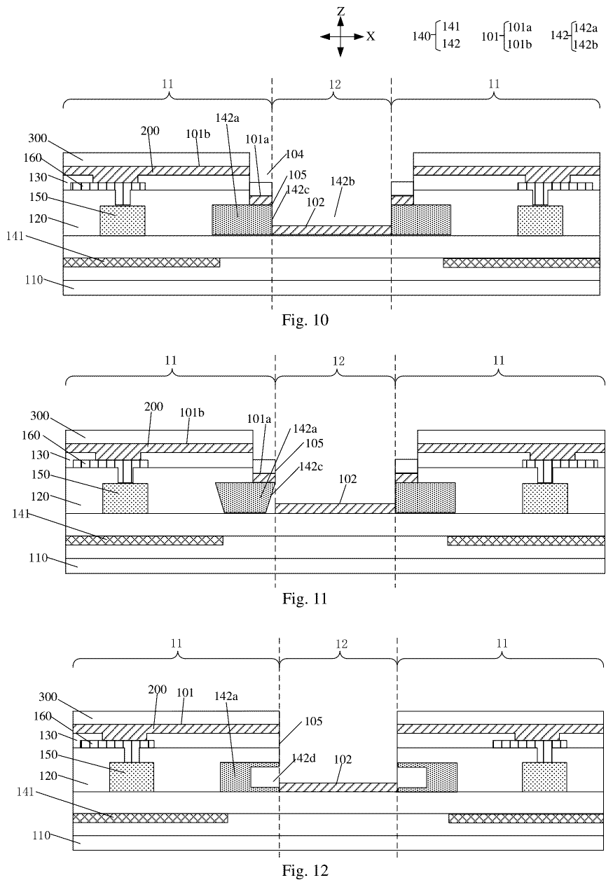

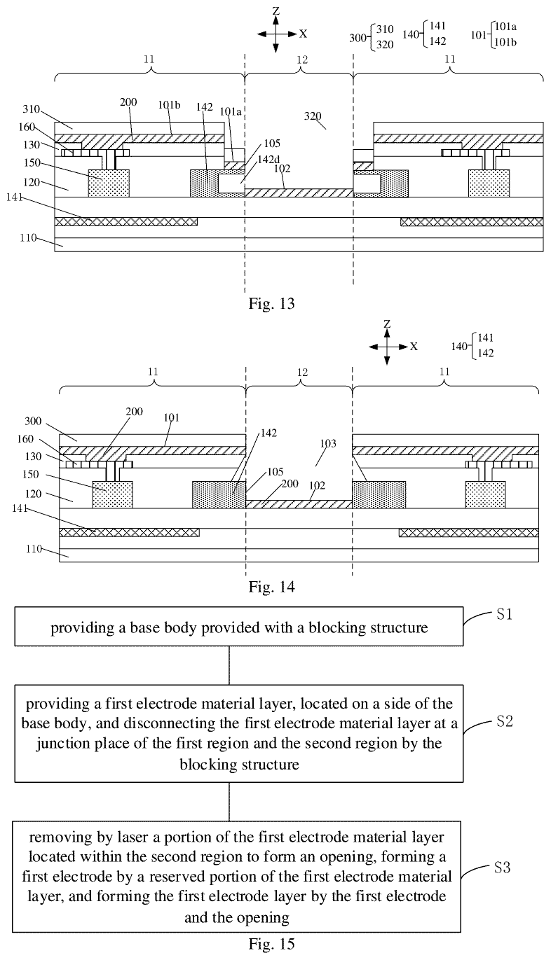

The arrangement of the position of the second sheltering layer 142 may be in various ways. As shown in FIG. 2, FIG. 3 and FIG. 6, the second sheltering layer 142 is located on the side of the planarized layer 120 away from the substrate 110. As shown in FIG. 7, FIG. 8, FIG. 10, FIG. 11, FIG. 12, FIG. 13 and FIG. 14, the second sheltering layer 142 is located on the side of the planarized layer 120 facing the substrate 110. As shown in FIG. 4, FIG. 5 and FIG. 9, the second sheltering layer 142 is located within the pixel defining layer 130 to further reduce the distance between the second sheltering layer 142 and the first electrode layer 300 in the thickness direction Z. In these embodiments, the pixel defining layer 130 may include a first sub-layer 130a and a second sub-layer 130b, and the second sheltering layer 142 may be located between the first sub-layer 130a and the second sub-layer 130b.

In some other embodiments, optionally, the base body 100 further includes the signal line layer 150 and the second electrode layer 160 located on the side of the signal line layer 150 away from the substrate 110, and the second sheltering layer 142 is arranged in the same layer as the signal line layer 150 or the second electrode layer 160, so that the second sheltering layer 142 can be prepared and formed in the same process step as the signal line layer 150 or the second electrode layer 160, which can simplify the preparation process of the display panel 10. As shown in FIG. 6, the second sheltering layer 142 is arranged in the same layer as the second electrode layer 160. As shown in FIG. 7, the second sheltering layer 142 is arranged in the same layer as the signal line layer 150.

In one embodiments, the signal line layer 150 includes, such as, at least one of a first conductive layer, a second conductive layer and a third conductive layer. Optionally, the signal line layer 150 includes a first conductive layer and a second conductive layer. The first conductive layer is arranged in the same layer as the second conductive layer, the first conductive layer and the second electrode layer 160 are located on two sides of the planarized layer 120 and connected with each other by passing through the planarized layer 120, and the second conductive layer is multiplexed as the second sheltering layer 142.

Optionally, as shown in FIG. 6, the second sheltering layer 142 is arranged in the same layer as the second electrode layer 160, so that the second sheltering layer 142 and the pixel electrode can be prepared and formed in the same process step, which can simplify the preparation process of the display panel 10, reduce the distance between the second sheltering layer 142 and the first electrode layer 300, and solve the problem that an edge of the first electrode 310 facing the opening 320 easily curls up.

Optionally, the first sheltering layer 141 is located on a side of the signal line layer 150 facing the substrate 110, so that the first sheltering layer 141 can shelter from the laser and improve the effect of the laser on elements in other layer structures in the base body 100.

In some optional embodiments, as shown in FIG. 2 to FIG. 14, the base body 100 is provided with the second avoidance slot 103, which is located within the second region 12. The first surface 101 and the second surface 102 are connected by a third surface 105 at the boundary between the first region 11 and the second region 12. The third surface 105 and at least a portion of the second surface 102 form an inner wall face of the second avoidance slot 103. Optionally, at least a portion of the second surface 102 may be used as a bottom wall face of the second avoidance slot 103, and the third surface 105 may be used as the inner wall face of the second avoidance slot 103. In one of the embodiments, the third surface 105 extends in the thickness direction Z of the display panel 10. In one of the embodiments, a size of the third surface 105 in the thickness direction Z of the display panel 10 is larger than a thickness of the first electrode 310 in the thickness direction Z of the display panel 10.

The second avoidance slot 103 penetrates through the pixel defining layer 130 and at least a portion of the planarized layer 120, or the second avoidance slot 103 penetrates through at least a portion of the pixel defining layer 130.

The second avoidance slot 103 is formed by patterning the base body 100, so that the height of the surface of the portion of the substrate 100 located within the second region 12 is relatively low. When the first electrode material layer for preparing the first electrode layer 300 is formed, the first electrode material layer is prone to be broken at an upper edge of the inner side wall face (i.e. the third surface 105) of the second avoidance slot 103. Thus, a portion of the first electrode material layer located within the first region 11 and a portion of the second electrode material layer located within the second region 12 are formed, so as to solve the problem that an edge of the first electrode 310 facing the second region 12 easily curls up, and ensure the encapsulation performance.

The second avoidance slot 103 may be arranged in various ways. The second avoidance slot 103 may be arranged to penetrate through at least a portion of the pixel defining layer 130. For example, the second avoidance slot 103 may be arranged to penetrate through a portion of pixel defining layer 130, and the second avoidance slot 103 is a recess formed on the pixel defining layer 130. The second avoidance slot 103 is made while the pixel defining layer 130 is patterned to form a pixel opening 320.

Alternatively, the second avoidance slot 103 completely penetrates through the pixel defining layer 130, the second avoidance slot 103 is a through hole formed in the pixel defining layer 130, the planarized layer 120 is exposed from the second avoidance slot 103, and the second surface 102 is a surface of the planarized layer 120 exposed from the second avoidance slot 103.

In some other embodiments, the second avoidance slot 103 may penetrate through the pixel defining layer 130 and at least a portion of the planarized layer 120. That is, the second avoidance slot 103 not only penetrates through the pixel defining layer 130, but also penetrates through at least a portion of the planarized layer 120. For example, the second avoidance slot 103 is arranged to penetrate through the whole pixel defining layer 130 and penetrate through a portion of the planarized layer 120, and the second avoidance slot 103 includes a through hole penetrating through the pixel defining layer 130 and a recess penetrating through a portion of the planarized layer 120; or the second avoidance slot 103 is arranged to completely penetrate through the pixel defining layer 130 and the planarized layers 120, that is, the second avoidance slot 103 is a through hole penetrating through the pixel defining layer 130 and the planarized layer 120.

In some optional embodiments, as shown in FIG. 9 and FIG. 10, the base body 100 is further provided with a first avoidance slot 104, the first avoidance slot 104 is located within the first region 11, the first avoidance slot 104 arranged to be adjacent to and communicated with the second avoidance slot 103, and at least a portion of the first surface 101 forms an inner wall face of the first avoidance slot 104. Optionally, at least a portion of the first surface 101 forms a bottom wall face of the first avoidance slot 104.

The first avoidance slot 104 may be arranged in various ways. The first avoidance slot 104 penetrates through the pixel defining layer 130 and at least a portion of the planarized layer 120, or the first avoidance slot 104 penetrates through at least a portion of the pixel defining layer 130.

In these optional embodiments, the base body 100 further includes the first avoidance slot 104 located within the first region 11. The first avoidance slot 104 is communicated with the second avoidance slot 103, that is, an avoidance slot extending from the second region 12 to the first region 11 is formed in the base body 100. When the first electrode material layer is processed by laser ashing, a portion of the first electrode material layer located within the second region 12 is removed to form the openings 320, and a portion of the first electrode material layer located within the first region 11 is reserved to form the first electrodes 310. A portion of the first electrode 310 is attached to the first surface 101 exposed from the first avoidance slot 104. Even if an edge of the first electrode 310 attached to the first surface 101 facing the second region 12 curls up, due to the existence of the first avoidance slot 104, the curling-up portion is hard to extend beyond the first avoidance slot 104, so that it can further reduce the impact of the curling-up edge of the first electrode 310 on the encapsulation effect of the encapsulation layer.

Optionally, as shown in FIG. 9 and FIG. 10, the first surface 101 includes a third sub-face 101a and a fourth sub-face 101b. The third sub-face 101a is located between the fourth sub-face 101b and the second surface 102 in the horizontal direction X. For example, as shown in FIG. 3, the third sub-face 101a is located between the fourth sub-face 101b and the first sub-face 102a of the second surface 102. The third sub-plane 101a is closer to the substrate 110 than the fourth sub-plane 101b to the substrate 110 in the thickness direction Z. Optionally, the third sub-face 101a may be the bottom wall face of the first avoidance slot 104. The third sub-face 101a is further away from the encapsulation layer. Even if an edge of the first electrode 310 attached to the third sub-face 101a facing the opening 320 curls up, the curling-up portion is hard to extend out of the first avoidance slot 104, so that it can further reduce the impact of the curling-up edge of the first electrode 310 facing the opening 320 on the encapsulation effect of the encapsulation layer.

Optionally, as shown in FIG. 9 and FIG. 10, when the first surface 101 includes the third sub-face 101a and the fourth sub-face 101b, the second sheltering layer 142 may be located within the pixel defining layer 130, or the second sheltering layer 142 may be arranged in the same layer as the signal line layer 150. In some other embodiments, when the first surface 101 includes the third sub-face 101a and the fourth sub-face 101b, the second sheltering layer 142 may be arranged in the same layer as the second electrode layer 160.

As described above, in the same way as the second avoidance slot 103, the first avoidance slot 104 may penetrate through the pixel defining layer 130 and at least a portion of the planarized layer 120, or the first avoidance slot 104 may penetrate through at least a portion of the pixel defining layer 130.

In some optional embodiments, as shown in FIG. 10, the second sheltering layer 142 includes a second sheltering part 142a for sheltering from the laser and a second through hole 142b for allowing the laser to pass through. The second sheltering part 142a is located within the first region 11, and the second through hole 142b is located within the second region 12. At least a portion of the second sheltering part 142a is exposed from the first avoidance slot 104. At least a portion of a surface of the second sheltering part 142a away from the substrate 110 forms the inner wall face of the first avoidance slot 104. Optionally, At least a portion of the surface of the second sheltering part 142a away from the substrate 110 forms the bottom wall face of the first avoidance slot 104.

In these optional embodiments, the second sheltering layer 142 includes the second sheltering part 142a and the second through hole 142b that is located within the second region 12, and an orthographic projection of the opening 320 on the substrate 110 coincides with an orthographic projection of the second through hole 142b on the substrate 110, so that the laser can pass through the second through hole 142b to remove the portion of the first electrode material layer located within the second region 12 to form the openings 320. The portion of the first electrode material layer located within the first region 11 is reserved to form the first electrodes 310. At least a portion of the second sheltering part 142a is exposed from the first avoidance slot 104. A surface of the second sheltering part 142a exposed from the first avoidance slot 104 is at least a portion of the first surface 101. Thus, the distance between a portion of the first electrode material layer located in the first avoidance slot 104 and the second sheltering part 142a can be reduced. When laser ashing, the problem that the edge of the first electrode 310 facing the opening 320 easily curls up can be solved, so as to ensure the encapsulation effect of the encapsulation layer.

Optionally, as shown in FIG. 11, in a direction from the pixel defining layer 130 to the substrate 110, a side wall face 142c on a side of the second sheltering section 142a close to the second through hole 142b is arranged obliquely towards a direction away from the second through hole 142b. In these embodiments, the side wall face 142c is at least a portion of the third surface 105. In these embodiments, when the first electrode material layer for preparing the first electrode layer 300 is formed, the first electrode material layer is hard to fall into a space below the side wall face 142c due to the side wall face 142c arranged obliquely in the above manner, so that the first electrode material layer is more prone to be broken near the side wall face 142c, so as to form a portion of the first electrode material layer located within the first region 11 and a portion of the first electrode material layer located within the second region 12, thereby solving the problem that the edge of the first electrode 310 facing the opening 320 easily curls up, and ensuring the encapsulation performance.

In some other optional embodiments, as shown in FIG. 12 and FIG. 13, the second sheltering part 142a is provided with a concave groove 142d, the concave groove 142d is provided with an opening facing the second through hole 142b.

In these optional embodiments, when the first electrode material layer for preparing the first electrode layer 300 is formed, the first electrode material layer is hard to fall into the concave groove 142d due to the concave groove 142d formed by recessing the side wall face 142c inwards, so that the first electrode material layer is more prone to be broken near the side wall face 142c, so as to form a portion of the first electrode material layer located within the first region 11 and a portion of the first electrode material layer located within the second region 12, thereby solving the problem that the edge of the first electrode 310 facing the opening 320 easily curls up, and ensuring the encapsulation performance.

In some examples, in order to facilitate forming the above-mentioned concave groove 142d, the second sheltering layer 142 may include a first structural layer, a second structural layer and a third structural layer in the thickness direction Z. The etching rate of the second structural layer is higher than the etching rate of the first structural layer and the etching rate of the third structural layer. In the process of obtaining the second sheltering part 142a by etching, the speed of etching the second structural layer is faster than the speed of etching the first structural layer and the speed of etching the third structural layer, so as to form the concave groove 142d. The etching rate of the first structural layer may be equal to the etching rate of the third structural layer. The material of the first structural layer may be the same as the material of the third structural layer. For example, the second sheltering layer 142 is a titanium-aluminum-titanium (i.e., Ti Al Ti) structure, that is, the first structural layer is a titanium layer, the second structural layer is an aluminium layer, and the third structural layer is a titanium layer. Alternatively, the second sheltering layer 142 may be of other materials, which is not limited herein.

As shown in FIG. 13, when the second sheltering part 142a is provided with the concave groove 142d, the first surface 101 may include the third sub-face 101a and the fourth sub-face 101b.

In some optional embodiments, as shown in FIG. 13, the first electrode layer 300 includes the first electrodes 310 and the openings 320, the first electrodes 310 are located within the first region 11, the openings 320 are located within the second region 12, and the orthographic projection of the opening 320 on the substrate 110 coincides with the orthographic projection of the second through hole 142b on the substrate 110.

In these optional examples, the first electrode layer 300 includes the first electrodes 310 and the openings 320. The openings 320 located within the second region 12 can improve the light transmittance of the first electrode layer 300. The first electrodes 310 located within the first region 11 can work with the pixel electrode to drive the light-emitting layer 200 located within the first region 11 to emit light. The orthographic projection of the opening 320 on the substrate 110 coincides with the orthographic projection of the second through hole 142b on the substrate 110, so that the laser passes through the second through hole 142b and processes the first electrode material layer by laser ashing to form the opening 320.

Optionally, a plurality of first regions 11 are provided, and the plurality of first regions 11 are distributed to be spaced apart from one another in the display region. Optionally, the second region 12 is arranged around at least a portion of the first region 11. Optionally, the second region 12 is located between two adjacent pixel openings to avoid affecting the light-emitting effect of the display panel 10.

In some optional embodiments, as shown in FIG. 14, when the second avoidance slot 103 passes through at least a portion of the pixel defining layer 130, in the direction from the pixel defining layer 130 to the substrate 110, the side wall face of the pixel defining layer 130 facing the second avoidance slot 103 is arranged obliquely towards a direction away from the second avoidance slot 103. According to the design, the first electrode material layer for preparing the first electrode layer 300 is hard to fall into a space below a side wall face of the pixel limiting layer 130 facing the second avoidance slot 103, so that the first electrode material layer can be broken near the side wall face of the pixel defining layer 130 facing the second avoidance slot 103. Optionally, when the second avoidance slot 103 penetrates through the pixel defining layer 130 and at least a portion of planarized layer 120, in the direction from the pixel defining layer 130 to the substrate 110, the pixel defining layer 130 and the side wall face of the planarized layer 120 facing the second avoidance slot 103 are arranged obliquely towards a direction away from the second avoidance slot 103. Optionally, the side wall face which is arranged obliquely may be located above the second sheltering layer 142.

The present application further provides a method of manufacturing a display panel, the display panel includes a display region, the display region includes a first region 11 and a second region 12, and the method includes:
S1: providing a base body 100, provided with a blocking structure;
S2: providing a first electrode material layer located on a side of the base body 100, so that the first electrode material layer is broken at the boundary between the first region 11 and the second region 12 by the blocking structure; and
S3: laser removing a portion of the first electrode material layer located within the second region 12 to form a plurality of openings 320, forming a plurality of first electrodes 310 by a reserved portion of the first electrode material layer, and forming the first electrode layer 300 by the first electrodes 310 and the openings 320.

In one of the embodiments, a surface of the base body 100 facing the first electrode layer 300 includes: a first surface 101 located within the first region 11, and a second surface 102 located within the second region 12. In a thickness direction Z of the display panel 10, the first surface 101 and the second surface 102 form a first height difference at a junction place of the first region 11 and the second region 12 to form a blocking structure. The step Si includes: providing a base body layer structure and removing a portion of the base body layer structure to form the base body 100.

In one of the embodiments, the base body layer structure includes: a substrate 110; a sheltering layer 140, located on a side of the substrate 110, the sheltering layer 140 including a sheltering part, and the sheltering part located within the first region 11; a planarized layer 120, located on a side of the sheltering layer 140 away from the substrate 110; and a pixel defining layer 130, located on a side of the planarized layer 120 away from the sheltering layer 140. The step S1 includes:
removing portions of the planarized layer 120 and the pixel defining layer 130 located above the sheltering part to form a first avoidance slot 104, and removing portions of the pixel defining layer 130 and the planarized layer 120 located within the second region 12 to form a second avoidance slot 103; in which the first avoidance slot 104 is adjacent to and communicated with the second avoidance slot 103, at least a portion of the first surface 101 forms a bottom wall face of the first avoidance slot 104, and at least a portion of the second surface 102 forms a bottom wall face of the second avoidance slot 103.

The present application further provides a display device, including the display panel in the above embodiments. The specific contents of the display panel may refer to the relevant instructions in the above-mentioned embodiments, which are not be repeated here. Specifically, the display device may be a device with the display function such as a mobile phone, a computer, a tablet computer, a television, electronic paper, which is not limited herein.

It should be clarified that each of the embodiments in the present application is described in a progressive manner, the same or similar portions among the various embodiments can be referred tone another, and each of the embodiments focuses on the differences from other embodiments. For the embodiments of the method and the embodiments of the display device, the relevant contents may refer to the description portion of the embodiments of the display panel. The present application is not limited to the specific steps and structures described above and shown in the drawings. Those skilled in the art may, after understanding the gist of the present application, make various changes, modifications and additions, or change the order among the steps. In addition, for the sake of brevity, the detailed description of the known method and technique is omitted here.

Those skilled in the art should understand that the above embodiments are exemplary and not restrictive. Different technical features appearing in different embodiments may be combined to achieve the beneficial effects. On the basis of studying the drawings, the description and the claims, those skilled in the art should understand and implement the other variations of the disclosed embodiments. In the claims, the term “including” does not exclude other devices or steps; the quantifier “a” does not exclude more than one; the terms “first” and “second” are used to designate names and not to indicate any particular order. Any reference numerals in the claims should not be construed as limiting the scope of protection. The functions of the multiple parts appearing in the claims may be realized by a single hardware or software module. The certain technical features recited in different dependent claims do not mean that these technical features cannot be combined to obtain the beneficial effects.

What is claimed is:

1. A display panel, comprising a display region comprising a first region and a second region,
and comprising
a base body;
a first electrode layer, at least a portion of the first electrode layer being located on a side of the base body, the first electrode layer comprising a plurality of first electrodes and a plurality of openings, the first electrodes being located within the first region, and the opening located within the second region, and
a blocking structure, configured to block the first electrodes from extending to the second region.

2. The display panel according to claim 1, wherein a surface of the base body facing the first electrode layer comprises
a first surface, located within the first region; and
a second surface, located within the second region;
in a thickness direction of the display panel, the first surface and the second surface form a first height difference at a junction place of the first region and the second region to form the blocking structure.

3. The display panel according to claim 2, wherein the first surface is closer to the first electrode layer than the second surface to the first electrode layer in the thickness direction of the display panel.

4. The display panel according to claim 3, wherein the second surface comprises a first sub-face and a second sub-face, the first sub-face is located between the first surface and the second sub-face in a horizontal direction perpendicular to the thickness direction of the display panel, and the first sub-face and the second sub-face form a second height difference in the thickness direction of the display panel.

5. The display panel according to claim 2, wherein the base body comprises
a substrate;
a planarized layer, located on a side of the substrate;
a pixel defining layer, located on a side of the planarized layer away from the substrate; and
a light-emitting layer, at least a portion of the light-emitting layer located on a side of the pixel defining layer away from the planarized layer;
wherein at least a portion of the first electrode layer is located on a side of the light-emitting layer away from the pixel defining layer.

6. The display panel according to claim 5, wherein the base body comprises at least one sheltering layer located within the first region, and an orthographic projection of the at least one sheltering layer on the substrate covers an orthographic projection of the first electrodes on the substrate.

7. The display panel according to claim 6, wherein the at least one sheltering layer comprises a first sheltering layer and a second sheltering layer, the second sheltering layer is closer to the first electrode layer than the first sheltering layer to the first electrode layer in the thickness direction of the display panel, and the second sheltering layer is closer to the second region than the first sheltering layer to the second region in a horizontal direction perpendicular to the thickness direction of the display panel.

8. The display panel according to claim 7, wherein the base body further comprises a signal line layer and a second electrode layer, the signal line layer is located on a side of the planarized layer facing the substrate, the second electrode layer is located on a side of the planarized layer away from the substrate, the signal line layer and the second electrode layer are located on two sides of the planarized layer and connected with each other by passing through the planarized layer, the first electrode layer and the second electrode layer are located on two sides of the light-emitting layer, and the second sheltering layer is arranged in the same layer as the signal line layer or the second electrode layer, or at least a portion of the signal line layer is multiplexed as the second sheltering layer.

9. The display panel according to claim 5, wherein the base body is provided with a second avoidance slot located within the second region, the first surface and the second surface are connected by a third surface at the junction place of the first region and the second region, and the third surface and at least a portion of the second surface form an inner wall face of the second avoidance slot.

10. The display panel according to claim 9, wherein
the base body is further provided with a first avoidance slot located within the first region, the first avoidance slot is adjacent to and communicated with the second avoidance slot, and at least a portion of the first surface forms an inner wall face of the first avoidance slot.

11. The display panel according to claim 10, wherein the base body comprises a second sheltering layer, the second sheltering layer comprises a second sheltering part for sheltering from laser and a second through hole for allowing the laser to pass through, the second sheltering part is located within the first region, the second through hole is located within the second region, and at least a portion of a surface of the second sheltering part away from the substrate forms the inner wall face of the first avoidance slot.

12. The display panel according to claim 11, wherein in a direction from the pixel defining layer to the substrate, a side wall face on a side of the second sheltering part close to the second through hole is arranged obliquely towards a direction away from the second through hole, or the second sheltering part is provided with a concave groove, the concave groove is provided with an opening facing the second through hole.

13. A display panel, comprising a display region comprising a first region and a second region, and comprising
a base body; and
a first electrode layer, at least a portion of the first electrode layer located on a side of the base body, the first electrode layer comprising a plurality of first electrodes and a plurality of openings, the first electrodes located within the first region, and the opening located within the second region;
a surface of the base body facing the first electrode layer comprising
a first surface, located within the first region; and
a second surface, located within the second region;
wherein in a thickness direction of the display panel, the first surface and the second surface form a first height difference at a junction place of the first region and the second region to form a blocking structure.

14. The display panel according to claim 13, wherein the first height difference is larger than a thickness of the first electrode in the thickness direction of the display panel.

15. The display panel according to claim 1,
wherein the first region is a first electrode material reserving region, the second region is a first electrode material removing region, the first electrodes are located within the first electrode material reserving region, the openings are located within the first electrode material removing region, and a portion of a first electrode material layer located within the first electrode material reserving region is reserved to form the first electrodes, and a portion of the first electrode material layer located within the first electrode material removing region is removed to form the openings;
the blocking structure is configured to disconnect a reserved portion of the first electrode material layer from a removed portion of the first electrode material layer before the opening is formed.

16. The display panel according to claim 15, wherein a surface of the base body facing the first electrode layer comprises:
a first surface, located within the first region; and
a second surface, located within the second region;
in a thickness direction of the display panel, the first surface and the second surface form a first height difference at a junction place of the first region and the second region to form a blocking structure.

17. A method of manufacturing the display panel according to claim 1, comprising
Providing the base body, provided with the blocking structure;
providing a first electrode material layer located on a side of the base body, and breaking the first electrode material layer at a junction place of the first region and the second region by the blocking structure; and
removing by laser a portion of the first electrode material layer located within the second region to form the opening, forming the first electrodes by a reserved portion of the first electrode material layer, and forming the first electrode layer by the first electrodes and the openings.

18. The method of manufacturing the display panel according to claim 17, wherein a step of the providing a base body provided with a blocking structure comprises
providing a base body layer structure, and removing a portion of the base body layer structure to form the base body so that a surface of the base body facing the first electrode layer comprising
a first surface, located within the first region; and
a second surface, located within the second region,
wherein in a thickness direction of the display panel, the first surface and the second surface form a first height difference at a junction place of the first region and the second region to form a blocking structure.

19. The method of manufacturing the display panel according to claim 18, wherein the base body layer structure comprises
a substrate;
a sheltering layer, located on a side of the substrate, the sheltering layer comprising a sheltering part, and the sheltering part located within the first region;
a planarized layer, located on a side of the sheltering layer away from the substrate; and
a pixel defining layer, located on a side of the planarized layer away from the sheltering layer;
wherein a step of the providing a base body layer structure and removing a portion of the base body layer structure to form the base body comprises:
removing portions of the planarized layer and the pixel defining layer located above the sheltering part to form a first avoidance slot, and removing portions of the pixel defining layer and the planarized layer located within the second region to form a second avoidance slot;
wherein the first avoidance slot is adjacent to and communicated with the second avoidance slot, at least a portion of the first surface forms an inner wall face of the first avoidance slot, and at least a portion of the second surface forms an inner wall face of the second avoidance slot.

20. A display device, comprising the display panel according to claim 1.
